(19) United States
(12) Patent Application Publication
(10) Pub. No.: US 2024/0213179 A1
(43) Pub. Date: Jun. 27, 2024

(54) SEMICONDUCTOR PACKAGE HAVING REINFORCING STRUCTURE

(71) Applicant: Samsung Electronics Co., Ltd., Suwon-si (KR)

(72) Inventor: Jaewoo Jeong, Suwon-si (KR)

(21) Appl. No.: 18/507,571

(22) Filed: Nov. 13, 2023

(30) Foreign Application Priority Data
Dec. 26, 2022 (KR) 10-2022-0184675

(51) Int. Cl. H01L 23/00; H01L 23/31; H01L 23/498; H01L 25/065

(52) U.S. Cl. CPC H01L 23/562; H01L 23/3128; H01L 23/49816; H01L 24/08; H01L 24/32; H01L 24/48; H01L 24/73; H01L 25/0657; H01L 2224/08145; H01L 2224/08225; H01L 2224/32145; H01L 2224/32225; H01L 2224/48147; H01L 2224/48227; H01L 2224/73215; H01L 2924/1815

(57) ABSTRACT

A semiconductor package comprising a stack structure disposed on a package substrate and that includes a lower structure and an upper structure on the lower structure, the upper structure including a plurality of semiconductor chips offset from each other in a first horizontal direction and stacked in a cascade structure, a reinforcing structure on the upper structure and including a reinforcing chip and an interfacial layer covering an upper surface of the reinforcing chip, and an encapsulant covering the package substrate. The plurality of semiconductor chips include a first semiconductor chip disposed directly below the reinforcing structure and a second semiconductor chip disposed directly below the first semiconductor chip. The reinforcing structure covers an overhanging portion of the first semiconductor chip in which the first semiconductor chip does not overlap the second semiconductor chip in a vertical direction, and the interfacial layer and the encapsulant include the same material.

### CROSS-REFERENCE TO RELATED APPLICATION(S)

This application claims benefit of priority to Korean Patent Application No. 10-2022-0184675 filed on Dec. 26, 2022 in the Korean Intellectual Property Office, the disclosure of which is incorporated herein by reference in its entirety.

### BACKGROUND

Aspects of the present inventive concept relate to a semiconductor package having a reinforcing structure.

As demand for high performance, high speed, and/or multifunctionality of semiconductor devices has increased, the degree of integration of semiconductor devices has increased. In manufacturing semiconductor devices with fine patterns corresponding to the trend for high integration of semiconductor devices, it is necessary to implement patterns having a fine width or a fine spacing. In addition, physical stability of semiconductor packages including fine-sized semiconductor chips is required.

### SUMMARY

An aspect of the present inventive concept is to provide a semiconductor package including a reinforcing structure covering an overhanging portion of the uppermost semiconductor chip of a stack structure.

According to an aspect of the present inventive concept, a semiconductor package includes: a package substrate; a stack structure disposed on the package substrate and including a lower structure and an upper structure on the lower structure, the upper structure including a plurality of semiconductor chips disposed to be offset from each other in a first horizontal direction and stacked in a cascade structure; a reinforcing structure disposed on the upper structure and including a reinforcing chip and an interfacial layer covering an upper surface of the reinforcing chip; and an encapsulant covering the package substrate and the stack structure and covering an upper surface of the reinforcing structure. The plurality of semiconductor chips may include a first semiconductor chip disposed directly below the reinforcing structure and a second semiconductor chip disposed directly below the first semiconductor chip. The reinforcing structure may cover an overhanging portion of the first semiconductor chip in which the first semiconductor chip does not overlap the second semiconductor chip in a vertical direction, the interfacial layer may include a material the same as that of the encapsulant.

According to another aspect of the present inventive concept, a semiconductor package includes: a package substrate; a stack structure disposed on the package substrate and including a lower structure and an upper structure on the lower structure, the upper structure including a plurality of semiconductor chips disposed to be offset from each other in a first horizontal direction and stacked in a cascade structure; a reinforcing structure disposed on the upper structure and including a lower reinforcing chip, an upper reinforcing chip, and an upper interfacial layer covering an upper surface of the upper reinforcing chip; and an encapsulant covering the package substrate and the stack structure and covering an upper surface of the reinforcing structure. The plurality of semiconductor chips may include a first semiconductor chip disposed directly below the reinforcing structure and a second semiconductor chip disposed directly below the first semiconductor chip. The reinforcing structure may cover an overhanging portion of the first semiconductor chip in which the first semiconductor chip does not overlap the second semiconductor chip in a vertical direction. The upper interfacial layer may include a material the same as that of the encapsulant.

According to another aspect of the present inventive concept, a semiconductor package includes: a package substrate; a stack structure disposed on the package substrate and including a plurality of semiconductor chips stacked in a zigzag pattern; a reinforcing structure disposed on the stack structure and including a reinforcing chip and an interfacial layer covering an upper surface of the reinforcing chip; and an encapsulant covering the package substrate and the stack structure and covering an upper surface of the reinforcing structure. The plurality of semiconductor chips may include a first semiconductor chip disposed directly below the reinforcing structure and a second semiconductor chip disposed direct below the first semiconductor chip. The reinforcing structure may cover an overhanging portion of the first semiconductor chip in which the first semiconductor chip does not overlap the second semiconductor chip in a vertical direction. The interfacial layer may include a material the same as that of the encapsulant.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view of a semiconductor package according to embodiments.

FIG. 2 is a plan view of the semiconductor package shown in FIG. 1.

FIG. 3 is a perspective view and a cross-sectional view illustrating a manufacturing method of a reinforcing structure according to an embodiment.

FIG. 4 is a plan view of a semiconductor package according to an embodiment.

FIGS. 5 and 6 are cross-sectional views of a semiconductor package according to embodiments.

FIGS. 7 and 8 are cross-sectional views of a semiconductor package according to embodiments.

FIGS. 9 and 10 are cross-sectional views of a semiconductor package according to embodiments.

### DETAILED DESCRIPTION

Hereinafter, embodiments of the present inventive concept will be described with reference to the accompanying drawings.

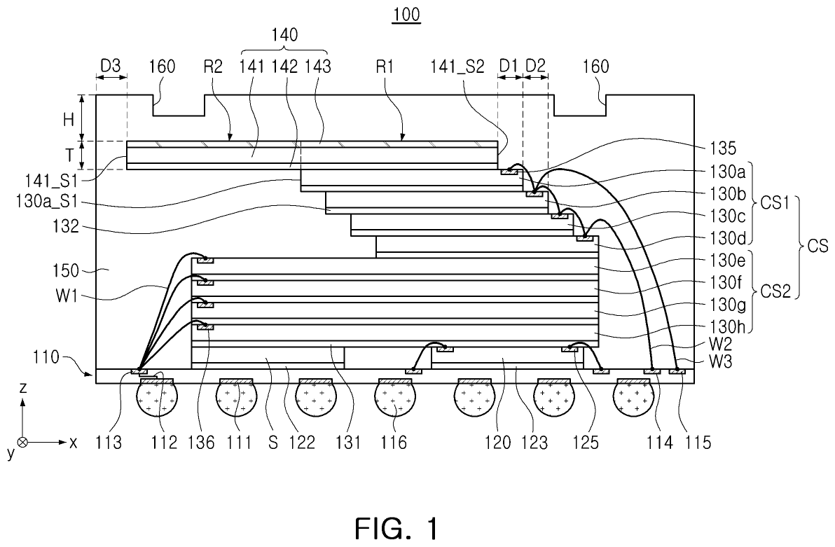

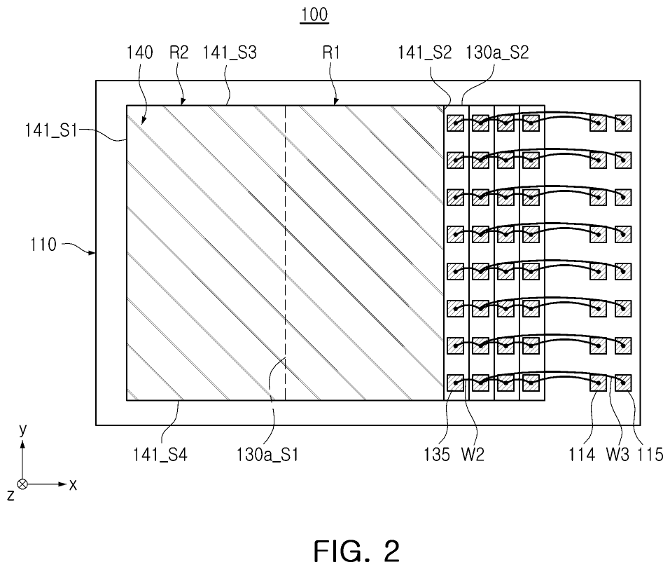

FIG. 1 is a cross-sectional view of a semiconductor package according to embodiments. FIG. 2 is a plan view of the semiconductor package shown in FIG. 1.

Referring to FIGS. 1 and 2, a semiconductor package 100 according to an embodiment of the present disclosure includes a package substrate 110, a connection terminal 116, a lower semiconductor chip 120, a support member S, a stack structure CS, a reinforcing structure 140, and an encapsulant 150.

The package substrate 110 may be a substrate for a semiconductor package, such as a printed circuit board (PCB), a ceramic substrate, or a tape wiring board. For example, the package substrate 110 may include or may be formed of a thermosetting resin, such as epoxy resin, a thermoplastic resin, such as polyimide, or a photosensitive insulating layer. Specifically, materials, such as prepreg, Ajinomoto build-up film (ABF), FR-4, bismaleimide triazine (BT), and photoimageable dielectric (PID) resin.

The package substrate 110 may include pads disposed on upper and lower surfaces. For example, the package substrate 110 may include a lower pad 111, a first upper pad 113, a second upper pad 114, and a third upper pad 115. The package substrate 110 may include internal wirings 112 electrically connecting the lower pad 111 and the first upper pad 113. Although not shown, internal wirings electrically connecting the second upper pad 114 and the third upper pad 115 to the lower pad 111 may be disposed within the package substrate 110. The lower pad 111, the internal wiring 112, and the upper pads 113, 114, and 115 may include a conductive material, such as metal, metal nitride, conductive carbon, or combinations thereof.

The connection terminal 116 may be disposed below the package substrate 110. The connection terminal 116 may be connected to the lower pad 111 disposed on a lower surface of the package substrate 110. The connection terminal 116 may be electrically connected to an external device, such as a main board. For example, the connection terminal 116 may include a solder ball, a conductive bump, or a flip-chip connection structure having a grid array, such as a pin grid array, a ball grid array, a land grid array, and the like. Spatially relative terms, such as “beneath,” “below,” “lower,” “above,” “upper” and the like, may be used herein for ease of description to describe positional relationships, such as illustrated in the figures, e.g. It will be understood that the spatially relative terms encompass different orientations of the device in addition to the orientation depicted in the figures.

The connection terminal 116 may include or may be formed of at least one of copper (Cu), nickel (Ni), tin (Sn), and an alloy (Sn—Ag) including tin. For example, the connection terminal 116 may include a pillar portion connected to the lower pad 111 and a solder portion below the pillar portion. The pillar portion may include or may be formed of at least one of copper (Cu) and nickel (Ni), and the solder portion may include or may be formed of an alloy (Sn—Ag) including tin.

The lower semiconductor chip 120 may be disposed on the package substrate 110. The semiconductor package 100 may further include a first adhesive layer 122 disposed below the lower semiconductor chip 120 and the support member S. In an embodiment, the lower semiconductor chip 120 may be mounted on the package substrate 110 by wire bonding and may be attached to the package substrate 110 by a second adhesive layer 123. The lower semiconductor chip 120 may include an inactive surface disposed to face the package substrate 110, an active surface disposed to face in an opposite direction of the package substrate 110, and a chip pad 125 disposed on the active surface. The chip pad 125 may be connected to a pad formed on an upper surface of the package substrate 110. The lower semiconductor chip 120 may include a system large scale integration (LSI), a logic circuit, a CMOS imaging sensor (CIS), and the like. The number and arrangement of the chip pads 125 are not limited to those illustrated and may be variously modified according to embodiments.

The support member S may be disposed below the stack structure CS and may support the stack structure CS. The first adhesive layer 122 may be disposed between the package substrate 110 and the support member S. The support member S may have substantially the same vertical thickness (e.g., in the Z-direction) as that of the lower semiconductor chip 120, and an upper surface of the support member S may be located on the same level in a vertical direction (e.g., the Z-direction) as that of the lower semiconductor chip 120. The support member S may include, for example, a semiconductor substrate, a metal or non-metal plate, or a printed circuit board. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The support member S may include a passive element therein. For example, the support member S may include a capacitor, a storage, an inductor, and the like. The support member S may provide functions, such as decoupling, filtering, resonance damping, and/or voltage regulation.

The stack structure CS may include an upper structure CS1 and a lower structure CS2 stacked on the package substrate 110. The lower structure CS2 may be stacked on the lower semiconductor chip 120 and the support member S, and the upper structure CS1 may be stacked on the lower structure CS2. The upper structure CS1 may include a plurality of stacked semiconductor chips 130a, 130b, 130c, and 130d, and the lower structure CS2 may include a plurality of stacked semiconductor chips 130e, 130f, 130g, and 130h.

In an embodiment, the semiconductor chips 130a, 130b, 130c, and 130d of the upper structure CS1 may be stacked in a cascade structure. For example, the semiconductor chips 130a, 130b, 130c, and 130d adjacent to each other in the vertical direction may be disposed to be offset in a direction perpendicular to the vertical direction (e.g., the X-direction). A side surface of the lowermost semiconductor chip 130d may be coplanar with a side surface of the lower structure CS2. The semiconductor chips 130a, 130b, 130c, and 130d of the upper structure CS1 may be stacked in a wire bonding manner. For example, active surfaces of the semiconductor chips 130a, 130b, 130c, and 130d of the upper structure CS1 may be disposed to face in an opposite direction of the package substrate 110, and first chip pads 135 may be disposed on the active surfaces. The first chip pads 135 may be electrically connected to the second upper pad 114 through wirings W2, and one of the first chip pads 135 may be electrically connected to the third upper pad 115 through wirings W3. A third adhesive layer 132 may be disposed below each of the semiconductor chips 130a, 130b, 130c, and 130d.

In an embodiment, the semiconductor chips 130e, 130f, 130g, and 130h of the lower structure CS2 may have the same horizontal length (e.g., in the X-direction) and are stacked such that side surfaces of the semiconductor chips 130e, 130f, 130g, and 130h are coplanar. A side surface of the lowermost semiconductor chip 130h may be coplanar with a side surface of the support member S. The semiconductor chips 130e, 130f, 130g, and 130h of the lower structure CS2 may be stacked in a wire bonding manner. For example, the active surfaces of the semiconductor chips 130e, 130f, 130g, and 130h of the lower structure CS2 may be disposed to face in the opposite direction of the package substrate 110, and second chip pads 136 may be disposed on the active surfaces. The second chip pads 136 may be electrically connected to the first upper pad 113 through wirings W1. A fourth adhesive layer 131 may be disposed below each of the semiconductor chips 130e, 130f, 130g, and 130h, and the fourth adhesive layers 131 may partially cover the wirings W1. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

In embodiments, the ‘active surface’ may refer to a region in which a semiconductor IC is formed on a front surface of the semiconductor substrate, and a ‘non-active surface’ may refer to a rear surface of the semiconductor substrate facing the front surface of the semiconductor substrate. For example, when any one semiconductor chip is a memory chip, the “active surface” may refer to a region in which a memory cell array including memory cells storing information of the memory chip and a semiconductor IC capable of performing an operation of storing information in the memory cells and erasing information stored in the memory cells are formed on the front surface of the semiconductor substrate, and the “non-active surface” may refer to a rear surface of the semiconductor substrate in which the memory cell array and the IC are not formed.

Each of the semiconductor chips 130a, 130b, 130c, 130d, 130e, 130f, 130g, and 130h of the stack structure CS may be a memory device, such as a non-volatile memory device or a volatile memory device. The memory device may include a NAND flash memory, a magnetic random access memory (MRAM), a phase-change random access memory (PRAM), a ferroelectric random access memory (FeRAM), a resistive random access memory (RRAM), an X-point random access memory (RAM), dynamic random access memory (DRAM), static random access memory (SRAM), high bandwidth memory (HBM), hybrid memory cubic (HMC), or combinations thereof. In an embodiment, the semiconductor chips 130e, 130f, 130g, and 130h of the lower structure CS2 may be DRAM chips, and the semiconductor chips 130a, 130b, 130c, and 130d of the upper structure CS1 may be NAND chips.

The type, number, size, and arrangement of the semiconductor chips 130a, 130b, 130c, 130d, 130e, 130f, 130g, and 130h are not limited to those illustrated and may be variously modified according to embodiments.

The adhesive layers 122, 123, 131, and 132 may be non-conductive adhesive films. In an embodiment, the adhesive layers 122, 123, 131, and 132 may include or may be formed of a polymer material having excellent thermal conductivity. For example, as the adhesive layers 122, 123, 131, and 132, a thermally conductive adhesive tape, thermally conductive grease, or a thermally conductive adhesive may be used.

The reinforcing structure 140 may be disposed on the stack structure CS. The reinforcing structure 140 may be disposed on the uppermost semiconductor chip 130a of the stack structure CS, and a horizontal length of the reinforcing structure 140 in the X-direction may be greater than a horizontal length of the semiconductor chip 130a in the X-direction. For example, the reinforcing structure 140 may be disposed above and in contact with the uppermost semiconductor chip 130a. In an embodiment, the reinforcing structure 140 may be disposed to be offset from the semiconductor chip 130a. For example, the reinforcing structure 140 may be disposed to be offset from the semiconductor chip 130a in a direction in which the semiconductor chips 130a, 130b, 130c, and 130d of the upper structure CS1 stacked in a cascade structure are offset from each other. In an embodiment, a distance D1 by which the reinforcing structure 140 is offset from the semiconductor chip 130a may be substantially equal to a distance D2 by which the semiconductor chip 130a is offset from the semiconductor chip 130b disposed directly therebelow. The distance D1 may be about 300 μm or greater. In an embodiment, the reinforcing structure 140 may cover an overhanging portion of the semiconductor chip 130a. Here, the ‘overhanging portion’ of the semiconductor chip 130a may refer to a portion in which the semiconductor chip 130a does not overlap the semiconductor chip 130b disposed directly therebelow in the vertical direction (e.g., the Z-direction). For example, the reinforcing structure 140 may include an overlapping region R1 vertically overlapping a portion of the semiconductor chip 130a and an overhanging region R2 not overlapping the semiconductor chip 130a in the vertical direction. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

In a structure in which semiconductor chips are stacked, when an impact is applied to the semiconductor package 100 or a main board on which the semiconductor package 100 is mounted, the overhanging portion of the semiconductor chip 130a located at the top of the stack structure CS may be vulnerable to the impact. However, since the semiconductor package 100 of the present disclosure includes the reinforcing structure 140 covering the overhanging portion of the semiconductor chip 130a, the occurrence of cracks in the overhanging portion may be prevented or reduced. A thickness T of the reinforcing structure 140 in the vertical direction may be about 50 μm or greater.

The reinforcing structure 140 may include a reinforcing chip 141, a fifth adhesive layer 142 and an interfacial layer 143. The reinforcing chip 141, the fifth adhesive layer 142, and the interfacial layer 143 may completely overlap each other in the vertical direction, and side surfaces of the reinforcing chip 141, the adhesive layer 142, and the interfacial layer 143 may be coplanar. In an embodiment, the reinforcing chip 141 may include a silicon layer, and the silicon layer may include or may be formed of, for example, at least one of monocrystalline silicon, polycrystalline silicon, and amorphous silicon. The reinforcing chip 141 may be a portion of a bulk silicon wafer. In an embodiment, the reinforcing chip 141 may include or may be formed of at least one of amorphous silicon, monocrystalline gallium arsenide, polycrystalline gallium arsenide, and amorphous gallium arsenide.

The reinforcing chip 141 may include a first side surface 141_S1, a second side surface 141_S2, a third side surface 141_S3, and a fourth side surface 141_S4. The first side surface 141_S1 may be a surface opposite to the second side surface 141_S2, and the first side surface 141_S1 and the second side surface 141_S2 may be spaced apart from each other in the X-direction. The third side surface 141_S3 may be a surface opposite to the fourth side surface 141_S4, and the third side surface 141_S3 and the fourth side surface 141_S4 may be spaced apart from each other in the Y-direction. The first side surface 141_S1 may be disposed relatively closer to a side surface of the encapsulant 150 than the second side surface 141_S2. A distance D3 between the first side surface 141_S1 and the side surface of the encapsulant 150 may be about 50 μm or greater. As described above, the reinforcing structure 140 may be disposed to be offset from the semiconductor chip 130a. For example, the second side surface 141_S2 of the reinforcing chip 141 (or the side surface of the reinforcing structure 140) may be spaced apart from a side surface of the semiconductor chip 130a. In an embodiment, the side surfaces (i.e., the first side surface 141_S1, the second side surface 141_S2, the third side surface 141_S3, and the fourth side surface 141_S4) of the reinforcing chip 141 may have the same length as a longer side of the semiconductor chip 130a. For example, the semiconductor chip 130a may include a first side surface 130a_S1, perpendicular to the X-direction and a second side surface 130a_S2, perpendicular to the Y-direction. The first side surface 130a_S1 may be a longer side, and the second side surface 130a_S2 may be a shorter side. For example, the length of the first side surface 130a_S1 may be greater than the length of the second side surface 130a_S2. The first side surface 141_S1 and the second side surface 141_S2 of the reinforcing chip 141 may have the same length as that of the first side surface 130a S1 of the semiconductor chip 130a, and the third side surface 141_S3 and the fourth side surface 141_S4 of the reinforcing chip 141 may be coplanar with a side surface of the semiconductor chip 130a. For example, the third side surface 141_S3 of the reinforcing chip 141 may be coplanar with the second side surface 130a_S2 of the semiconductor chip 130a. In an embodiment, the first side surface 141_S1, the second side surface 141_S2, the third side surface 141_S3, and the fourth side surface 141_S4 of the reinforcing chip 141 may be substantially the same length.

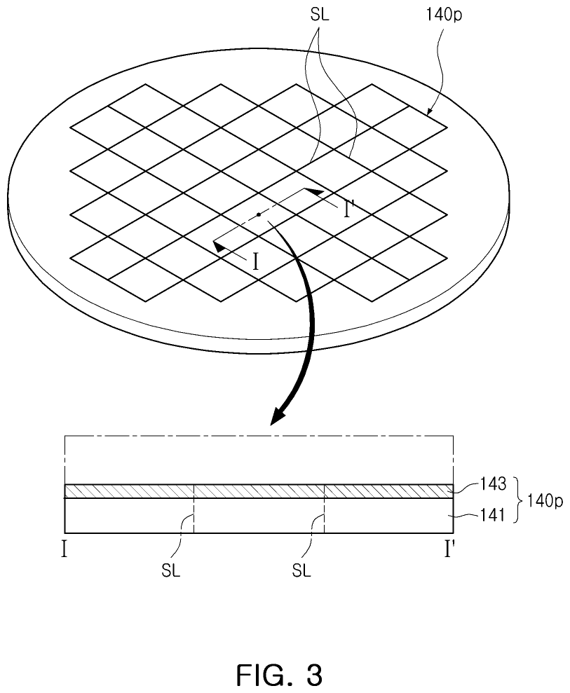

In an embodiment, the reinforcing chip 141 may include silicon, and a crystal orientation of the first side surface 141_S1, the second side surface 141_S2, the third side surface 141_S3, and the fourth side surface 141_S4 may be <110>. Silicon may have different physical properties, such as electrical conductivity, resistance, and strength depending on the crystal orientation. For example, when the crystal orientation of one surface of the silicon layer is <100>, fracture toughness K_{IC} may be 0.95 MPa√m. When the crystal orientation of one side of the silicon layer is <110>, the fracture toughness may be 0.90 MPa√m. That is, since the fracture toughness is smaller when the crystal orientation of the side surfaces of the reinforcing chip 141 is <110>, a cut surface may be relatively smooth in a sawing process described below with reference to FIG. 3. For example, the cut surface after the sawing process may be flat and may not have irregularities. Accordingly, crack seeds are relatively small, and thus, strength of the reinforcing chip 141 may be increased and the occurrence of cracks may be reduced.

The fifth adhesive layer 142 may cover a lower surface of the reinforcing chip 141 and may partially contact the semiconductor chip 130a. The fifth adhesive layer 142 may attach and fix the reinforcing structure 140 to the stack structure CS. The adhesive layer 142 may be a non-conductive adhesive film and may include or may be formed of the same material as that of the adhesive layers 122, 123, 131, and 132.

The interfacial layer 143 may cover an upper surface of the reinforcing chip 141. The interfacial layer 143 may include or may be formed of the same material as that of the encapsulant 150 to be described later. For example, the interfacial layer 143 may be a resin including or formed of an EMC or polyimide. The resin may include or may be formed of a bisphenol-group epoxy resin, a polycyclic aromatic epoxy resin, an o-cresol novolac epoxy resin, a biphenyl-group epoxy resin, or naphthalene-group epoxy resin. When different materials are bonded, cracks may occur during a manufacturing process because of different coefficients of thermal expansion. However, since the reinforcing structure 140 of the semiconductor package 100 of the present disclosure includes the interfacial layer 143 including the same material as that of the encapsulant 150, the occurrence of cracks between the reinforcing structure 140 and the encapsulant 150 may be prevented and reduced. That is, since the interfacial layer 143 prevents crack seeds from occurring, the reinforcing chip 141 may be protected, and the occurrence of cracks of the reinforcing chip 141 may be prevented or reduced. A thickness of the interfacial layer 143 in the vertical direction may be about 5 μm to about 6 μm.

FIG. 3 is a perspective view and a cross-sectional view illustrating a manufacturing method of a reinforcing structure according to an embodiment.

Referring to FIG. 3, a preliminary reinforcing structure 140p including the reinforcing chip 141 and the interfacial layer 143 on the reinforcing chip 141 is illustrated. In an embodiment, the preliminary reinforcing structure 140p may be formed by coating a silicon wafer with an insulating material. Thereafter, the reinforcing structure 140 may be formed by a sawing process of cutting the silicon wafer and the insulating material along a scribe line. The adhesive layer 142 may be disposed below the reinforcing chip 141 before or after the sawing process.

Since the reinforcing chip 141 is formed by cutting a silicon wafer, if a length of each side of the reinforcing chip 141 is not equal, physical characteristics of each side may be different. For example, each side may have a different strength. However, as described above, since the first side surface 141_S1, the second side surface 141_S2, the third side surface 141_S3, and the fourth side surface 141_S4 of the reinforcing chip 141 may be substantially equal, each side may have the same strength and the occurrence of cracks may be reduced.

Referring back to FIGS. 1 and 2, the encapsulant 150 may cover the package substrate 110, the stack structure CS, and the reinforcing structure 140. The encapsulant 150 may include or may be formed of a thermosetting polymer material. In an embodiment, the encapsulant 150 may be a resin including or formed of an epoxy molding compound (EMC) or polyimide. For example, the resin may include or may be formed of a bisphenol-group epoxy resin, a polycyclic aromatic epoxy resin, an o-cresol novolac epoxy resin, a biphenyl-group epoxy resin, or naphthalene-group epoxy resin. As described above, the encapsulant 150 may include or may be formed of the same material as that of the interfacial layer 143.

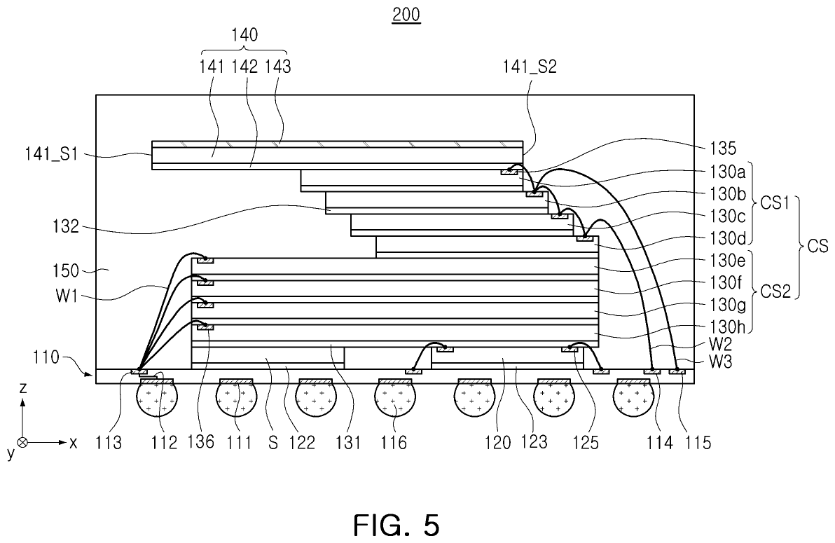

In an embodiment, a recess 160 for marking may be formed on an upper surface of the encapsulant 150. The recess 160 may be formed by partially etching the upper surface of the encapsulant 150. The recess 160 may extend downwardly (i.e., in the vertical direction) from the upper surface of the encapsulant 150, but may not expose the upper surface of the reinforcing structure 140. A height H from the upper surface of the reinforcing structure 140 (e.g., the upper surface of the interfacial layer 143) to the uppermost surface of the encapsulant 150 may be about 100 μm or greater. The recess 160 may also be formed in the semiconductor packages 200, 300, 400, 500, 600, and 700 shown in FIGS. 5 to 10.

In the following embodiments, only components modified from the components described above with reference to FIGS. 1 and 2 will be described. Descriptions of components identical to or similar to those described above with reference to FIGS. 1 and 2 may be equally applied.

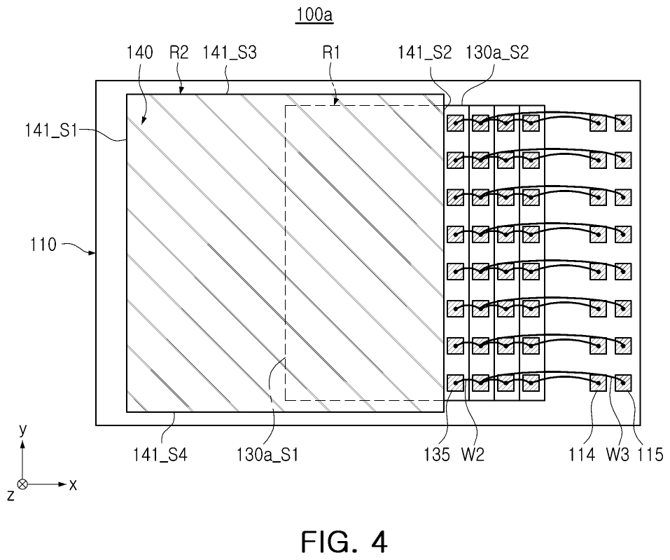

FIG. 4 is a plan view of a semiconductor package according to an embodiment.

Referring to FIG. 4, a semiconductor package 100a may include a reinforcing structure 140 disposed on the semiconductor chip 130a. In an embodiment, a length of at least one of the first side surface 141_S1, the second side surface 141_S2, the third side surface 141_S3, and the fourth side surface 141_S4 of the reinforcing chip 141 may be greater than a length of the longer side of the semiconductor chip 130a. For example, the lengths of the first side surface 141_S1 and the second side surface 141_S2 of the reinforcing structure 140 may be greater than the length of the first side surface 130a_S1 of the semiconductor chip 130a. In an embodiment, the lengths of the first side surface 141_S1, the second side surface 141_S2, the third side surface 141_S3, and the fourth side surface 141_S4 may be substantially the same. The overhanging region R2 of the reinforcing structure 140 may further extend in the Y-direction from the second side surface 130a_S2 of the semiconductor chip 130a. The horizontal length of the overhanging region R2 of the reinforcing structure 140 in the Y-direction may be greater than the horizontal length of the overlapping region R1 in the Y-direction.

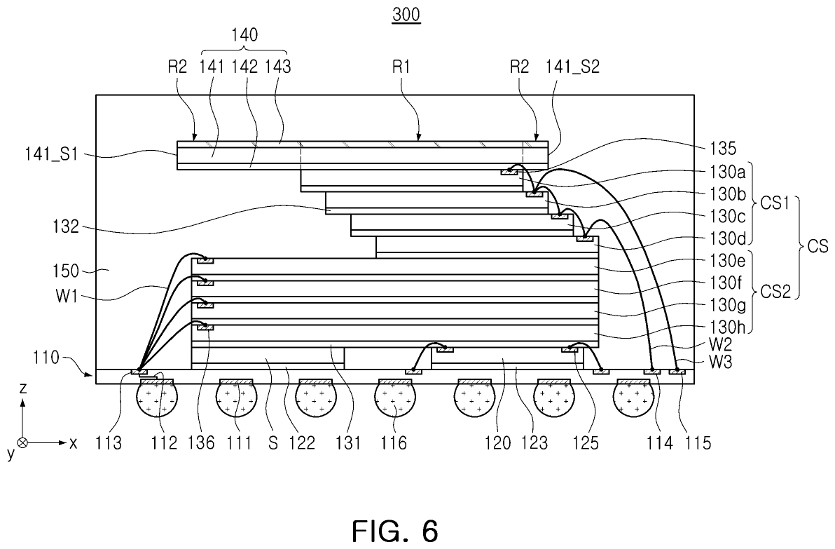

FIGS. 5 and 6 are cross-sectional views of a semiconductor package according to embodiments.

Referring to FIG. 5, a semiconductor package 200 may include a reinforcing structure 140 disposed on the semiconductor chip 130a. In an embodiment, the second side surface 141_S2 of the reinforcing chip 141 may be coplanar with a side surface of the semiconductor chip 130a. The semiconductor chip 130a may completely overlap the reinforcing structure 140 in a vertical direction. The fifth adhesive layer 142 of the reinforcing structure 140 may cover the wiring W2 connected to the semiconductor chip 130a.

Referring to FIG. 6, a semiconductor package 300 may include a reinforcing structure 140 disposed on the semiconductor chip 130a. In an embodiment, the reinforcing structure 140 may include a plurality of overhanging regions R2. For example, the reinforcing structure 140 may include the overlapping region R1 overlapping the semiconductor chip 130a and two overhanging regions R2 spaced apart from each other in the X-direction with the overlapping region R1 interposed therebetween. The semiconductor chip 130a may completely overlap the reinforcing structure 140 in a vertical direction. The fifth adhesive layer 142 of the reinforcing structure 140 may cover the wiring W2 connected to the semiconductor chip 130a.

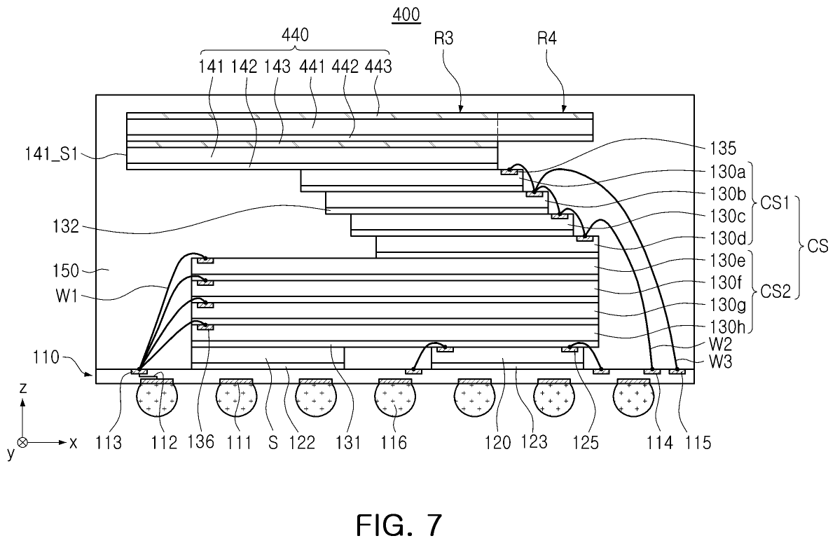

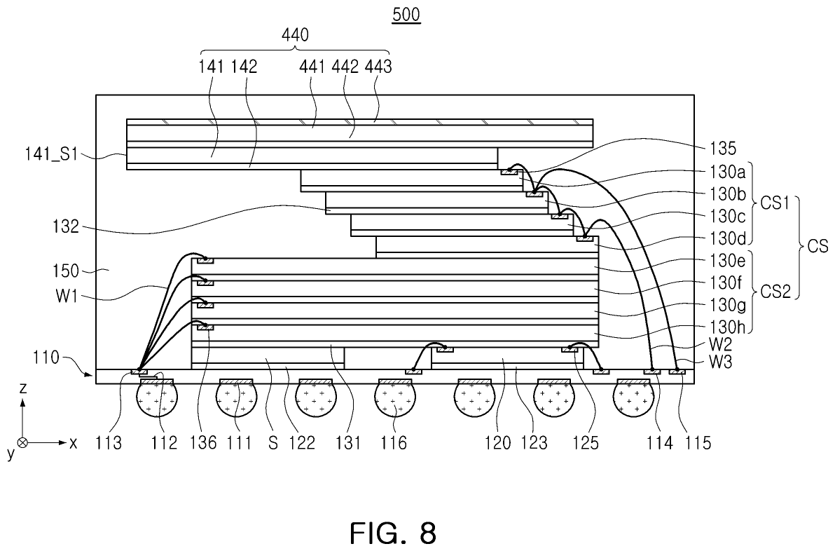

FIGS. 7 and 8 are cross-sectional views of a semiconductor package according to embodiments.

Referring to FIG. 7, a semiconductor package 400 may include a reinforcing structure 440 disposed on the semiconductor chip 130a. For example, the reinforcing structure 440 may be disposed above and in contact with the semiconductor chip 130a. In an embodiment, the reinforcing structure 440 may include a reinforcing chip 141, an adhesive layer 142, an interfacial layer 143, a reinforcing chip 441, an adhesive layer 442, and an interfacial layer 443. Since the reinforcing chip 141, the adhesive layer 142, and the interfacial layer 143 may have the same configuration as that described above with reference to FIGS. 1 and 2, a detailed description thereof may be omitted. The reinforcing chip 141, the adhesive layer 142, and the interfacial layer 143 may form a ‘lower reinforcing structure,’ and the reinforcing chip 141, the adhesive layer 142, and the interfacial layer 143 of the lower reinforcing structure may be referred to as a lower reinforcing chip, a lower adhesive layer and a lower interfacial layer, respectively. The reinforcing chip 441, the adhesive layer 442, and the interfacial layer 443 may form an ‘upper reinforcing structure,’ and the reinforcing chip 441, the adhesive layer 442, and the interfacial layer 443 of the upper reinforcing structure may be referred to as an upper reinforcing chip, an upper adhesive layer, and an upper interfacial layer, respectively. The upper reinforcing structure may include an overlapping region R3 vertically overlapping (i.e., in the vertical direction) the lower reinforcing structure and an overhanging area R4 not overlapping the lower reinforcing structure in the vertical direction. The overhanging region R4 may overlap the upper stack structure CS in the vertical direction.

The upper adhesive layer 442 may be disposed on an upper surface of the lower interfacial layer 143 and may cover a lower surface of the upper reinforcing chip 441. A horizontal length of the upper reinforcing chip 441 in the X-direction may be greater than a horizontal length of the lower reinforcing chip 141 in the X-direction. The upper reinforcing chip 441 may be coplanar with the first side surface 141_S1 of the lower reinforcing chip 141, but is not limited thereto. The upper reinforcing chip 441 may include the same material as that of the lower reinforcing chip 141. A crystal orientation of the side surfaces of the upper reinforcing chip 441 may be <110>. The upper interfacial layer 443 may cover an upper surface of the upper reinforcing chip 441. The upper interfacial layer 443 may include the same material as that of the lower interfacial layer 143 and the encapsulant 150. The number and arrangement of the reinforcing chips are not limited to those illustrated and may be variously modified according to embodiments.

Referring to FIG. 8, a semiconductor package 500 may include a reinforcing structure 440 disposed on the semiconductor chip 130a. In an embodiment, the reinforcing structure 440 may include a lower reinforcing chip 141, a lower adhesive layer 142, an upper reinforcing chip 441, an upper adhesive layer 442, and an upper interfacial layer 443. Unlike the reinforcing structure 440 illustrated in FIG. 7, the lower interfacial layer 143 may be omitted. The upper adhesive layer 442 may cover a lower surface of the upper reinforcing chip 441 and may contact an upper surface of the lower reinforcing chip 141.

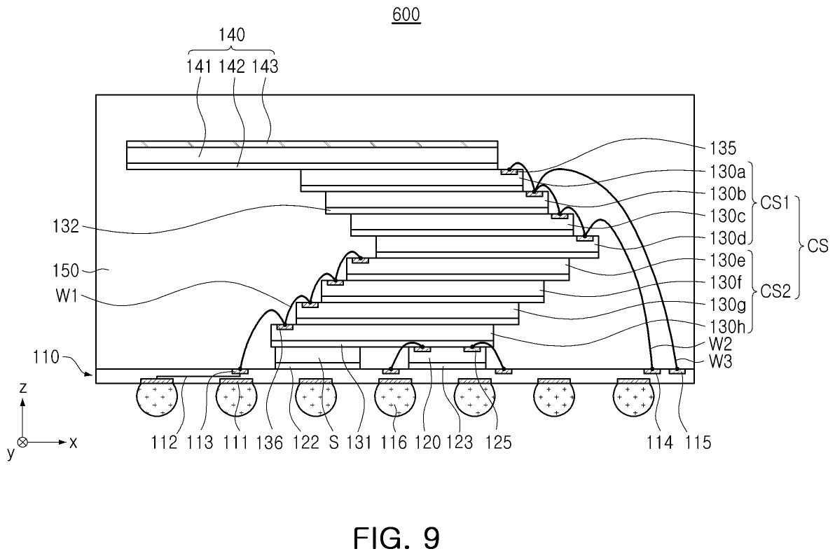

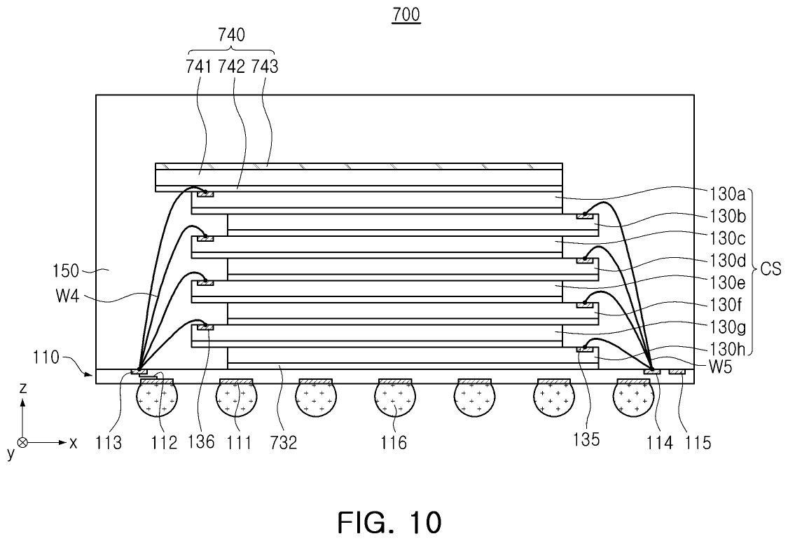

FIGS. 9 and 10 are cross-sectional views of a semiconductor package according to embodiments.

Referring to FIG. 9, a semiconductor package 600 may include a lower semiconductor chip 120 disposed on a package substrate 110, a support member S, a lower structure CS2 and an upper structure CS1. The lower semiconductor chip 120 and the support member S may be disposed below the lower structure CS2 and may support the lower structure CS2. Since the lower semiconductor chip 120, the support member S, and the upper structure CS1 may have the same structure as that described above with reference to FIG. 1, a detailed description thereof may be omitted.

In an embodiment, the lower structure CS2 may include semiconductor chips 130e, 130f, 130g, and 130h stacked in a cascade structure. The semiconductor chips 130e, 130f, 130g, and 130h adjacent to each other may be disposed to be offset from each other in the X-direction. An offset direction of the semiconductor chips 130e, 130f, 130g, and 130h of the lower structure CS2 may be different from an offset direction of the semiconductor chips 130a, 130b, 130c, and 130d of the upper structure CS1.

Referring to FIG. 10, the semiconductor package 700 may include a stack structure CS disposed on a package substrate 110 and a reinforcing structure 740 on the stack structure CS. The stack structure CS may include semiconductor chips 130a, 130b, 130c, 130d, 130e, 130f, 130g, and 130h stacked in a zigzag pattern and a sixth adhesive layer 732 disposed below each of the semiconductor chips 130a, 130b, 130c, 130d, 130e, 130f, 130g, and 130h. The semiconductor chips 130a, 130b, 130c, 130d, 130e, 130f, 130g, and 130h may be mounted in a wire bonding manner. For example, the wiring W4 may electrically connect the second chip pads 136 disposed on the upper surfaces of the semiconductor chips 130a, 130c, 130e, and 130 to the first upper pad 113. The wiring W5 may electrically connect the first chip pads 135 disposed on the upper surfaces of the semiconductor chips 130b, 130d, 130f, and 130h to the second upper pad 114.

The reinforcing structure 740 may be disposed on the uppermost semiconductor chip 130a of the stack structure CS. For example, the reinforcing structure 140 may be disposed above and in contact with the uppermost semiconductor chip 130a. The reinforcing structure 740 may cover an overhanging portion in which the semiconductor chip 130a does not overlap the semiconductor chip 130b in the vertical direction. At least one of side surfaces of the reinforcing structure 740 may be coplanar with a side surface of the semiconductor chip 130a. The reinforcing structure 740 may include a reinforcing chip 741, an adhesive layer 742, and an interfacial layer 743. The adhesive layer 742 may cover the wiring W4 connected to the semiconductor chip 130a.

According to embodiments of the inventive concept, the semiconductor package includes the reinforcing structure covering the overhanging portion of the uppermost semiconductor chip of the stack structure, thereby reducing the occurrence of cracks in the semiconductor chip. In addition, since the reinforcing structure includes the interfacial layer, the occurrence of cracks between the reinforcing structure and the encapsulant may be reduced.

While embodiments have been shown and described above, it will be apparent to those skilled in the art that modifications and variations could be made without departing from the scope of the present inventive concept as defined by the appended claims.

What is claimed is:

1. A semiconductor package comprising:
a package substrate;
a stack structure disposed on the package substrate and including a lower structure and an upper structure on the lower structure, the upper structure including a plurality of semiconductor chips disposed to be offset from each other in a first horizontal direction and stacked in a cascade structure;
a reinforcing structure disposed on the upper structure and including a reinforcing chip and an interfacial layer covering an upper surface of the reinforcing chip; and
an encapsulant covering the package substrate and the stack structure and covering an upper surface of the reinforcing structure,
wherein the plurality of semiconductor chips include a first semiconductor chip disposed directly below the reinforcing structure and a second semiconductor chip disposed directly below the first semiconductor chip,
wherein the reinforcing structure covers an overhanging portion of the first semiconductor chip in which the first semiconductor chip does not overlap the second semiconductor chip in a vertical direction, and
wherein the interfacial layer includes a material the same as that of the encapsulant.

2. The semiconductor package of claim 1, wherein the interfacial layer includes an epoxy resin compound (EMC).

3. The semiconductor package of claim 1, wherein the reinforcing chip includes at least one of monocrystalline silicon, polycrystalline silicon, and amorphous silicon.

4. The semiconductor package of claim 1, wherein a thickness of the reinforcing structure is about 50 μm or greater.

5. The semiconductor package of claim 1, wherein each of a plurality of side surfaces of the reinforcing chip have the same length.

6. The semiconductor package of claim 1, wherein
the first semiconductor chip includes a first side surface with a first length and a second side surface with a second length that is a shorter than the first length, and
a length of each of the side surfaces of the reinforcing chip is the same as a length of the first side surface of the first semiconductor chip.

7. The semiconductor package of claim 6, wherein at least one of the side surfaces of the reinforcing chip is coplanar with the second side surface of the first semiconductor chip.

8. The semiconductor package of claim 1, wherein
the reinforcing chip includes a first side surface, perpendicular to the first horizontal direction, and a second side surface opposite to the first side surface,
the first side surface is disposed to be closer to the encapsulant than the second side surface, and
a distance between the first side surface and the encapsulant is about 50 μm or greater.

9. The semiconductor package of claim 1, wherein
the reinforcing structure is disposed to be offset from the first semiconductor chip in the first horizontal direction, and
a distance by which the reinforcing structure is offset from the first semiconductor chip is equal to a distance by which the first semiconductor chip is offset from the second semiconductor chip.

10. The semiconductor package of claim 1, wherein a height from the upper surface of the reinforcing structure to an uppermost surface of the encapsulant is about 100 μm or greater.

11. The semiconductor package of claim 1, wherein
the encapsulant includes a recess extending in the vertical direction from an upper surface, and
the reinforcing structure is not exposed by the recess.

12. The semiconductor package of claim 1, wherein the lower structure includes semiconductor chips stacked to completely overlap each other.

13. The semiconductor package of claim 1, wherein the reinforcing chip includes a silicon layer, and a crystal orientation of side surfaces of the reinforcing chip is <110>.

14. The semiconductor package of claim 1, wherein
the reinforcing structure includes an overlapping region overlapping the first semiconductor chip and an overhanging region not overlapping the first semiconductor chip, and
a horizontal length of the overhanging region in a second horizontal direction, intersecting the first horizontal direction, is greater than a horizontal length of the overlapping region in the second horizontal direction.

15. The semiconductor package of claim 1, wherein a horizontal length of the reinforcing structure in the first horizontal direction is greater than a horizontal length of the first semiconductor chip in the first horizontal direction.

16. The semiconductor package of claim 1, wherein the lower structure includes semiconductor chips stacked in a cascade structure.

17. A semiconductor package comprising:
a package substrate;
a stack structure disposed on the package substrate and including a lower structure and an upper structure on the lower structure, the upper structure including a plurality of semiconductor chips disposed to be offset from each other in a first horizontal direction and stacked in a cascade structure;
a reinforcing structure disposed on the upper structure and including a lower reinforcing chip, an upper reinforcing chip, and an upper interfacial layer covering an upper surface of the upper reinforcing chip; and
an encapsulant covering the package substrate and the stack structure and covering an upper surface of the reinforcing structure,
wherein the plurality of semiconductor chips include a first semiconductor chip disposed directly below the reinforcing structure and a second semiconductor chip disposed directly below the first semiconductor chip,
wherein the reinforcing structure covers an overhanging portion of the first semiconductor chip in which the first semiconductor chip does not overlap the second semiconductor chip in a vertical direction, and
wherein the upper interfacial layer includes a material the same as that of the encapsulant.

18. The semiconductor package of claim 17, wherein
the reinforcing structure further includes a lower interfacial layer disposed between the lower reinforcing chip and the upper reinforcing chip, and
the lower interfacial layer covers an upper surface of the lower reinforcing chip.

19. The semiconductor package of claim 17, wherein a horizontal length of the upper reinforcing chip in the first horizontal direction is greater than a horizontal length of the lower reinforcing chip in the first horizontal direction.

20. A semiconductor package comprising:
a package substrate;
a stack structure disposed on the package substrate and including a plurality of semiconductor chips stacked in a zigzag pattern;
a reinforcing structure disposed on the stack structure and including a reinforcing chip and an interfacial layer covering an upper surface of the reinforcing chip; and
an encapsulant covering the package substrate and the stack structure and covering an upper surface of the reinforcing structure,
wherein the plurality of semiconductor chips include a first semiconductor chip disposed directly below the reinforcing structure and a second semiconductor chip disposed direct below the first semiconductor chip,
wherein the reinforcing structure covers an overhanging portion of the first semiconductor chip in which the first semiconductor chip does not overlap the second semiconductor chip in a vertical direction, and
wherein the interfacial layer includes a material the same as that of the encapsulant.
